(19) United States
(12) Patent Application Publication
(10) Pub. No.: US 2008/0169566 A1
(43) Pub. Date: Jul. 17, 2008

(54) Press-Fit Diode Having a Silver-Plated Wire Termination

(76) Inventors: Richard Spitz, Reutlingen (DE); Mario Einsiedler, Budapest (HU); Stefan Schoene, Wannweil (DE)

Correspondence Address: KENYON & KENYON LLP, ONE BROADWAY, NEW YORK, NY, 10004, US

(21) Appl. No.: 10/566,811

(22) PCT Filed: Jun. 19, 2004
(86) PCT No.: PCT/DE2004/001285

§ 371 Date: Nov. 16, 2007

(30) Foreign Application Priority Data
Aug. 8, 2003 (DE) 103 38 408.1
Oct. 9, 2003 (DE) 103 46 855.2

(51) Int. Cl. H01L 23/48; H01L 21/60

(52) U.S. Cl. 257/762; 438/106; 257/E23.01; 257/E21.511

(57) ABSTRACT

A press-fit diode, e.g., for rectifier applications, includes a diode chip, a base contact for pressing into a substrate, which base contact forms a first terminal of the press-fit diode, and a wire contact which forms a second terminal of the press-fit diode. An easily solderable corrosion-resistant press-fit diode is provided by coating the wire contact at least partially with a silver layer, the base contact having no silver layer.

### FIELD OF THE INVENTION

The present invention relates to a press-fit diode and a method for manufacturing such a press-fit diode.

### BACKGROUND INFORMATION

The design of medium- and high-performance diodes as press-fit diodes is known in the art. Such diodes are used primarily in rectifier applications, and are an important component of bridge rectifiers for today's motor vehicle generators.

Known rectifier diodes include a base contact which forms a first terminal of the press-fit diode, a wire contact which forms the second terminal of the press-fit diode, and the actual diode semiconductor chip which is soldered in between the contacts. The base contact is used for pressing the diode into a recess in a substrate element. A printed circuit board, for example, may be soldered to the wire contact.

FIG. 1 shows a press-fit diode known in the art, having a base contact 3, a diode chip 7, and a wire contact 2. As can be seen, base contact 3 has a wider press-in section which at the same time produces a thermal and electrical connection with the substrate element. Diode chip 7 is attached by, for example, soldering or welding between base contact 3 and wire contact 2. The particular solder layers are designated by reference numeral 8.

Wire contact 2 includes a broadened wire head 5 for attaching diode chip 7, and a narrower wire shaft 4 which is externally accessible. For a motor vehicle generator, for example, wire shaft 4 is connected to one phase of the stator windings.

Both base contact 3 and wire contact 2 are usually made of copper and plated with a nickel layer 6, which in particular is used as a corrosion barrier between the copper and the material of the substrate element (e.g., aluminum). Press-fit diode 1 is further encased by a plastic sheathing 9.

As mentioned, wire contact 2 may be attached to a printed circuit board by either soldering or welding. If the wire contact is soldered, the entire metal surface of diode 1 is electroplated with tin. Tin plating is usually performed using a drum tin plating process in which press-fit diodes 1 are electroplated in bulk. This process is particularly simple and economical.

However, for operation under severe environmental conditions, such as in a motor vehicle, for example, problems often arise for tin-plated press-fit diodes, such as the problems recited below.

Severe temperature fluctuations and vibratory stress in the rectifier of a motor vehicle generator result in micromotions between the tin surface of the base contact and the wall of the substrate element into which the diode is pressed. The use of aluminum cooling plates as substrate elements thus causes fretting corrosion, on account of which high contact resistance results, which may in turn result in overheating and failure of press-fit diode 1.

An object of the present invention, therefore, is to provide a press-fit diode, and a method for manufacturing a press-fit diode, which is less susceptible to fretting corrosion of the base contact, and whose wire contact has an easily solderable surface. Furthermore, the press-fit diode should be as economical as possible to manufacture.

### SUMMARY

In accordance with the present invention, the wire contact for the press-fit diode is provided at least partially with a surface layer of silver, and the base contact is produced from a material or provided with a metal layer which causes the least possible amount of corrosion of the material of the substrate element. Silver plating has particularly good soldering characteristics, and in addition has a melting point over a temperature of approximately 300° C., which arises during the manufacturing of the press-fit diode, for example, when the diode chip is soldered in between the base contact and the wire contact, or when the sheathing is cured. Silver is therefore preferred over other possible materials.

Because of the great difference in electrochemical potential with respect to aluminum, the base contact is not silver-plated, and is provided with a nickel layer, for example. Nickel is much less noble than silver, and therefore has less of a tendency toward corrosion with aluminum. The disadvantage of different surface coatings for the base contact and the wire contact, however, is that it is not possible to silver-plate the press-fit diode in the economical bulk process.

Therefore, the wire contacts are silver-plated individually (before the press-fit diode is assembled). In an example embodiment, not the entire wire contact but only a portion thereof is silver-plated. According to one example embodiment of the present invention, a section of the wire contact used for attaching the diode chip is not provided with the silver layer. Completely silver-plating the wire contact is usually disadvantageous, since the silver forms an alloy with the solder used for soldering the diode chip, the melting point of the alloy being too low for further processing of the press-fit diode, such as the sheathing with plastic, for example. For this reason the region for attaching the diode chip may be recessed.

For manufacturing the partially silver-plated wire contacts, the wire contacts are, for example, inserted in a rack with the wire shafts pointing downward, and the wire shafts are immersed in an electroplating vat.

FIG. 1 shows a conventional press-fit diode known in the art.

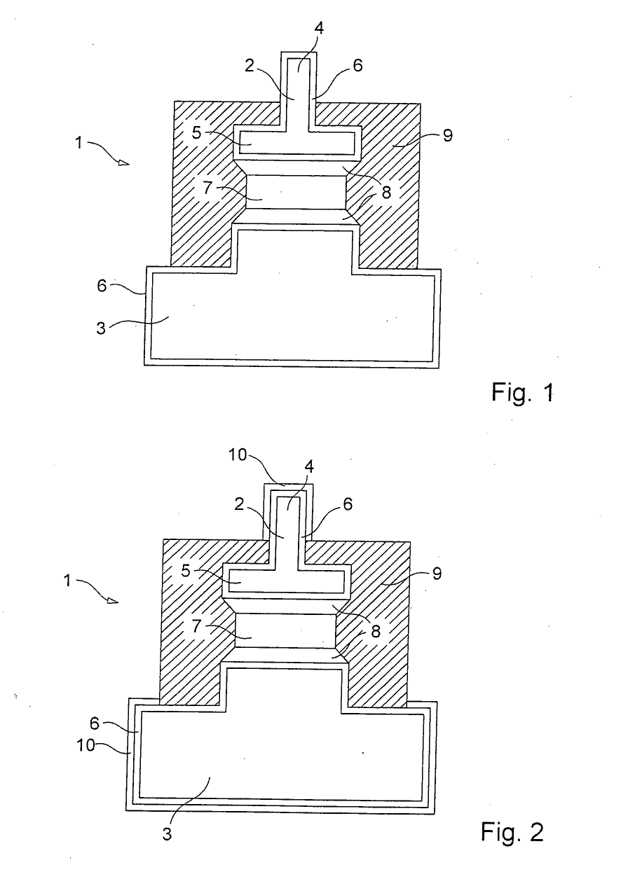

FIG. 2 shows a press-fit diode having silver plating according to a first example embodiment of the present invention.

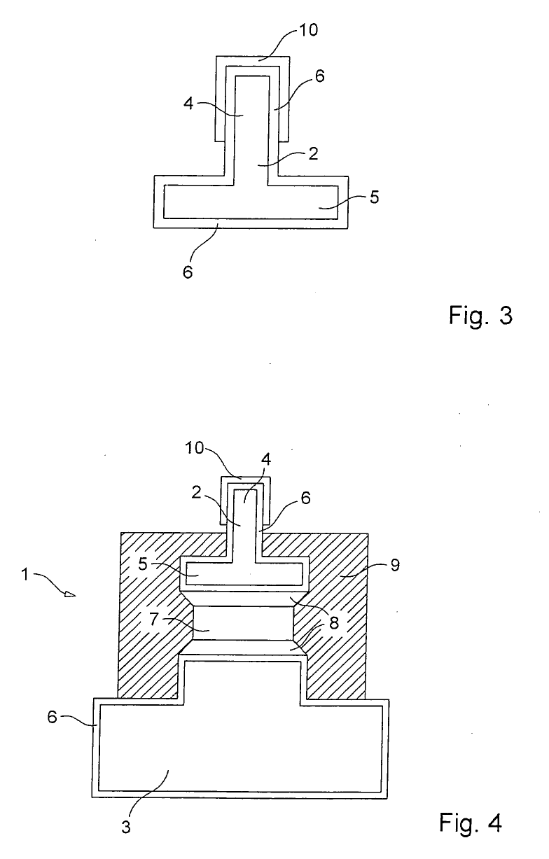

FIG. 3 shows a wire contact having a partial silver plating.

FIG. 4 shows a press-fit diode having a partially silver-plated wire contact and a base contact which is not silver-plated.

### DETAILED DESCRIPTION

FIG. 2 shows a press-fit diode, whose contacts are provided with an additional silver layer 10. Press-fit diode 1 includes a base contact 3, a wire contact 2, and a diode semiconductor chip 7 which is soldered in between contacts 2 and 3. The solder layer is designated by reference numeral 8.

Base contact 3 includes a broadened section for pressing into a substrate element, such as an aluminum plate, for example. At the same time, pressing in produces a durable thermal and electrical contact.

Wire contact 2 includes a wire head 5 which is used for connecting to diode chip 7, and a wire shaft 4 by which press-fit diode 1 may be connected to a printed circuit board, for example.

Base contact 3 and wire contact 2 are made of copper which is provided with a nickel layer 6. A central section of press-fit diode 1 is sheathed in plastic 9 to protect diode chip 7.

The contact regions protruding from sheathing 9 are provided with a silver layer 10. The nickel layer is used as a diffusion barrier between the copper and the silver layer 10. For production of silver layer 10 the diodes may, for example, be electroplated in bulk in a drum process.

However, when substrate elements made of certain materials, such as aluminum, for example, are used, this example embodiment has the disadvantage that increased corrosion may occur between the silver and the substrate material.

Another example embodiment of the present invention in which this problem does not occur is illustrated in FIGS. 3 and 4.

FIG. 3 shows a wire contact 2 having a partial silver plating. The silver plating is provided only on wire shaft 4 of wire contact 2, but not on section 5 to which diode chip 7 is attached.

Such a partially silver-plated wire contact 2 may be manufactured, for example, by inserting wire contacts 2 individually into a rack (with wire shafts 4 pointing downward) and immersing wire shafts 4 in an electroplating vat. Wire contact 2 is then joined to other components 3, 7 and sheathed in plastic 9. Base contact 3 is not silver-plated in this case, and is made of, for example, copper provided with a nickel layer 6. When a substrate element made of aluminum is used, this results in much less electrolytic corrosion between nickel layer 6 and the aluminum, compared to that between silver layer 10 and aluminum.

The result is a press-fit diode having a very easily solderable wire contact 2, and a base contact 3 which may be pressed into an aluminum substrate without corrosion problems.

1-8. (canceled)

9. A press-fit diode, comprising:
a diode chip;
a base contact for pressing the press-fit diode into a substrate, wherein the base contact is attached to the diode chip and forms a first terminal of the press-fit diode; and
a wire contact which forms a second terminal of the press-fit diode, wherein the wire contact is attached to the diode chip and is at least partially provide with a silver layer.

10. The press-fit diode as recited in claim 9, wherein a section of the wire contact attached to the diode chip is not provided with the silver layer.

11. The press-fit diode as recited in claim 10, wherein the base contact is not provided with a silver layer.

12. The press-fit diode as recited in claim 10, wherein the wire contact further includes a nickel layer on which the silver layer is applied.

13. A method for manufacturing a press-fit diode, comprising:
providing a diode chip;
providing a base contact configured for pressing the press-fit diode into a substrate, wherein the base contact forms a first terminal of the press-fit diode;
providing a wire contact which forms a second terminal of the press-fit diode, wherein the wire contact is at least partially provided with a silver layer; and
fixedly connecting the wire contact, the base contact, and the diode chip to one another.

14. The method as recited in claim 13, wherein a section of the wire contact attached to the diode chip is not provided with the silver layer.

15. The method as recited in claim 13, wherein the base contact is not provided with a silver layer.

16. The method as recited in claim 14, wherein the base contact is not provided with a silver layer.

17. The method as recited in claim 13, wherein the wire contact is made of copper, and wherein the wire contact is further provided with a nickel layer on which the silver layer is applied.

18. The method as recited in claim 14, wherein the wire contact is made of copper, and wherein the wire contact is further provided with a nickel layer on which the silver layer is applied.
